(19) United States
(12) Patent Application Publication
(10) Pub. No.: US 2017/0030493 A1
(43) Pub. Date: Feb. 2, 2017

(54) STRUCTURE OF WATER-COOLING PIPING SYSTEM

(71) Applicant: EVGA CORPORATION, New Taipei City (TW)

(72) Inventor: TAI-SHENG HAN, New Taipei City (TW)

(21) Appl. No.: 14/814,517

(22) Filed: Jul. 31, 2015

(51) Int. Cl. F16L 9/19; H05K 7/20

(52) U.S. Cl. CPC F16L 9/20; H05K 7/20272

(57) ABSTRACT

A water-cooling piping system generally includes at least one water-cooling heat dissipation device, at least one heat dissipation conduit connected to one side of the water-cooling heat dissipation device, a hot flow tube arranged in the heat dissipation conduit, a cold flow tube arranged in the heat dissipation conduit and beside the hot flow tube, and an insulator arranged in the heat dissipation conduit. The insulator surrounds an outside wall of each of the hot flow tube and the cold flow tube to have the hot flow tube and the cold flow tube isolated from and independent of each other. With such an arrangement, the hot flow tube and the cold flow tube are arranged in the heat dissipation conduit to form an integrated structure so that the space occupied by the tubes can be reduced and the installation of the heat dissipation conduit and the water-cooling heat dissipation device can be simplified. In addition, the insulator is provided to isolate the hot flow tube and the cold flow tube from each other so as to effectively improve the overall water cooling effect.

### (a) TECHNICAL FIELD OF THE INVENTION

The present invention relates generally to a structure of a water-cooling piping system, and more particularly to a structure of a water-cooling piping system that has a reduced size, is easy to install, and has a better effect of cooling.

### (b) DESCRIPTION OF THE PRIOR ART

Electronic components of an electronic device, such as central processing unit (CPU), may generate a large amount of heat during the operation thereof. Lacking immediate dissipation of the heat would lead to an excessively high temperature of the electronic component. Since the electronic components usually exhibit a reduced operation performance, or may event burn out, if they are put in operations in a high temperature. Thus, to reduce the temperature of an electronic component, it is commonplace to add a heat dissipation device to the electronic component in order to dissipate heat efficiently. However, the sizes of electronic components are increasingly reduced so that it is difficult to add multiple heat dissipation devices in a narrow space of an electronic device for dissipating heat through convection of heated air.

Thus, a water-cooling heat dissipation device is available for dissipating heat from an electronic component, this being a new contemporary trend. Such a device comprises a water inlet opening (tube) and a water outlet opening (tube). When such a water-cooling heat dissipation device is put into operation, internal components thereof are activated to draw in coolant liquid from the water inlet opening and to discharge the coolant liquid that has absorbed heat from the electronic component through the water outlet opening so as to achieve the purpose of circulating cooling for efficient heat exchange.

However, such a water-cooling heat dissipation device exhibits drawbacks that require further improvement:

(1) The water inlet tube and the water outlet tube are arranged separately and thus occupy a large amount of space.

(2) The water inlet tube and the water outlet tube must be installed individually, making the operation complicated.

(3) It is hard to distinguish the hot tube and the cold tube from each other, making it easy to have them installed oppositely.

Thus, it is a challenge of the present inventor and those involved in this business to provide a solution to overcome such problems.

### SUMMARY OF THE INVENTION

In view of the above problems, the present invention aims to provide a water-cooling piping system that has a reduced size, is easy to install, and provides a better effect of cooling.

The primary object of the present invention is to have a cold flow tube and a hot flow tube of a heat dissipation conduit combined as an integrated structure in order to reduce the overall size and to include an insulator to isolate the hot flow tube and the cold flow tube from each other inside the heat dissipation conduit so as to make the installation easy and simple and to reduce human errors happening in the installation.

To achieve the above object, the present invention provides a structure that comprises at least one heat dissipation conduit. The heat dissipation conduit has an end connected to at least one water-cooling heat dissipation device. The heat dissipation conduit comprises a hot flow tube arranged therein. The heat dissipation conduit also comprises a cold flow tube arranged therein and beside the hot flow tube. The heat dissipation conduit further comprises an insulator arranged therein. The insulator surrounds an outside wall of each of the hot flow tube and the cold flow tube so as to have the hot flow tube and the cold flow tube isolated from and independent of each other. As such, the heat dissipation conduit that is connected to the water-cooling heat dissipation device is constructed as an integrated structure with the hot flow tube and the cold flow tube collectively arranged in the heat dissipation conduit, this in combination with a foolproof arrangement greatly simplifying the installation operation and also helping reduce unexpected events resulting from carelessness happening in assembly. Further, the heat dissipation conduit comprises an insulator therein to effectively isolate the hot flow tube and the cold flow tube from each other so that mutual influence between the two can be eliminated during dissipation of heat thereby improving overall heat dissipation performance With the above-described technique, the drawbacks of a conventional water-cooling heat dissipation device that the size is bulky, the assembly is complicated, distinction of hot and cold tubes is difficult, and human errors may readily occur can be overcome and the above-identified advantages can be achieved.

The foregoing objectives and summary provide only a brief introduction to the present invention. To fully appreciate these and other objects of the present invention as well as the invention itself, all of which will become apparent to those skilled in the art, the following detailed description of the invention and the claims should be read in conjunction with the accompanying drawings. Throughout the specification and drawings identical reference numerals refer to identical or similar parts.

Many other advantages and features of the present invention will become manifest to those versed in the art upon making reference to the detailed description and the accompanying sheets of drawings in which a preferred structural embodiment incorporating the principles of the present invention is shown by way of illustrative example.

### BRIEF DESCRIPTION OF THE DRAWINGS

FIG. 1 is a perspective view showing a preferred embodiment of the present invention.

FIG. 2 is an exploded view showing the preferred embodiment of the present invention.

FIG. 2A is an enlarged view of a portion of FIG. 2.

FIG. 3 is a cross-sectional view of the preferred embodiment of the present invention taken along line A-A of FIG. 1.

FIG. 3A is an enlarged view of a portion of FIG. 3.

FIG. 4 is a schematic view illustrating an operation of the preferred embodiment of the present invention.

FIG. 4A is an enlarged view of a portion of FIG. 4.

FIG. 5 is another schematic view illustrating an operation of the preferred embodiment of the present invention.

FIG. 6 is a schematic view showing another embodiment of the present invention.

FIG. 6A is an enlarged view of a portion of FIG. 6.

### DETAILED DESCRIPTION OF THE PREFERRED EMBODIMENTS

The following descriptions are exemplary embodiments only, and are not intended to limit the scope, applicability or configuration of the invention in any way. Rather, the following description provides a convenient illustration for implementing exemplary embodiments of the invention. Various changes to the described embodiments may be made in the function and arrangement of the elements described without departing from the scope of the invention as set forth in the appended claims.

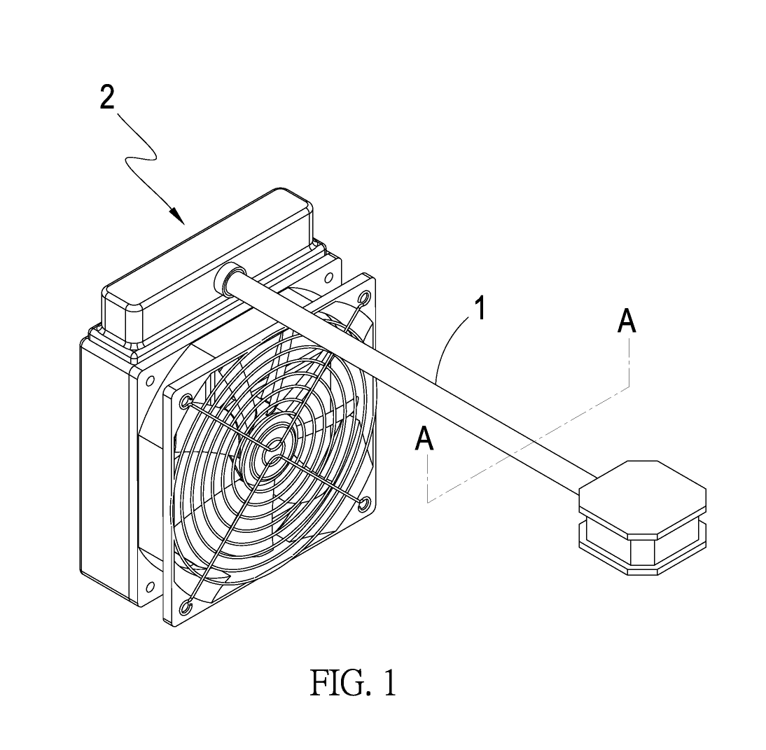

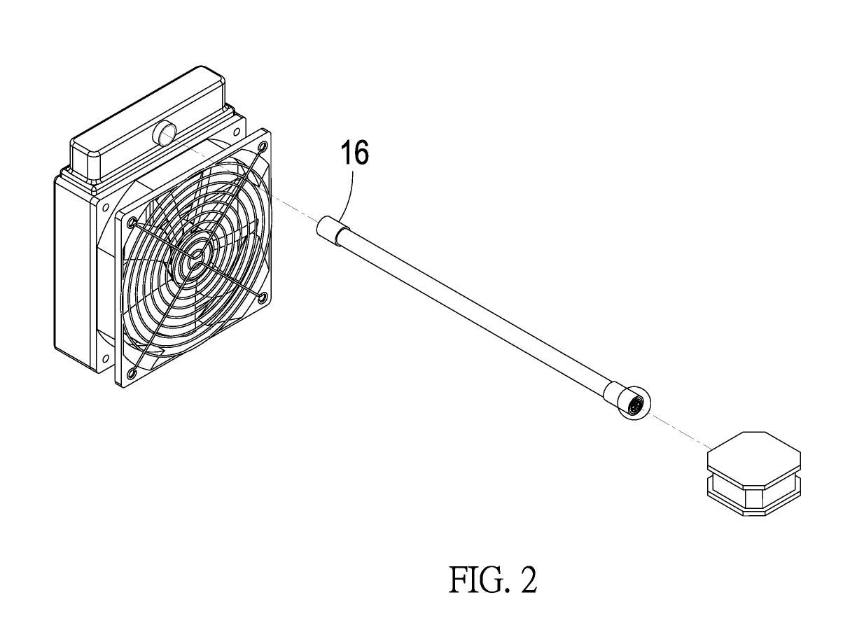

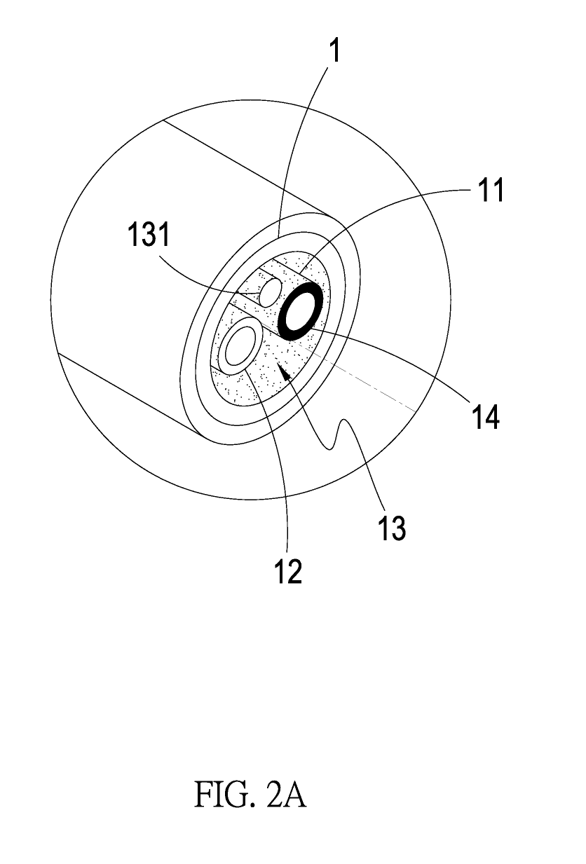

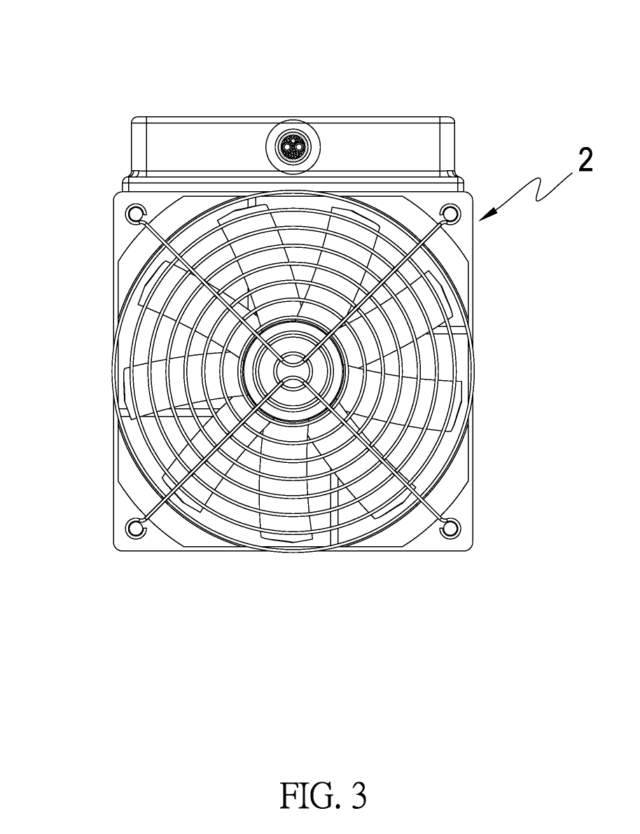

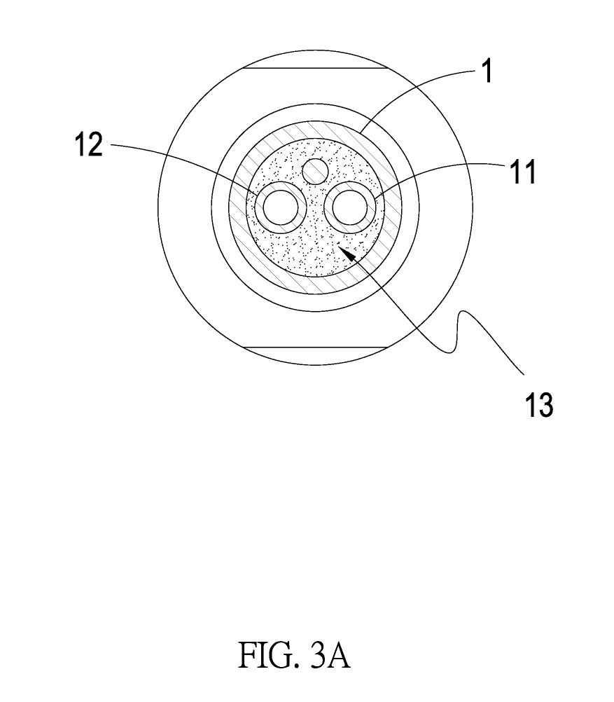

Referring to FIGS. 1, 2, 2A, 3, and 3A, which are respectively a perspective view and an exploded view of a preferred embodiment of the present invention, an enlarged view of a portion of FIG. 2, a cross-sectional view taken along line A-A of FIG. 1, and an enlarged view of a portion of FIG. 3, these drawings clearly show that the present invention comprises:

at least one water-cooling heat dissipation device 2, the water-cooling heat dissipation device 2 being a water-cooling heat dissipation fan;

at least one heat dissipation conduit 1 connected to the water-cooling heat dissipation device 2, the heat dissipation conduit 1 having a connection end that comprises at least one identification section 14 for distinguishing a hot flow tube 11 and a cold flow tube 12 that will be further discussed from each other, the heat dissipation conduit 1 having one end to which a quick connector 16 is mounted;

a hot flow tube 11, which is arranged in the heat dissipation conduit 1;

a cold flow tube 12, which is arranged in the heat dissipation conduit 1 and located beside the hot flow tube 11; and

an insulator 13, which is arranged in the heat dissipation conduit 1 in such a way that the insulator 13 surrounds an outside wall of each of the hot flow tube 11 and the cold flow tube 12 so as to have the hot flow tube 11 and the cold flow tube 12 isolated from and independent of each other, the insulator 13 comprising at least one electrically conductive element 131 arranged therein.

The structure of the present invention can be appreciated from the above description. An application based on such an arrangement may provide various advantages, including helping reduce the space occupied, simplifying the operation of installation, reducing human error in assembly, and improving cooling performance.

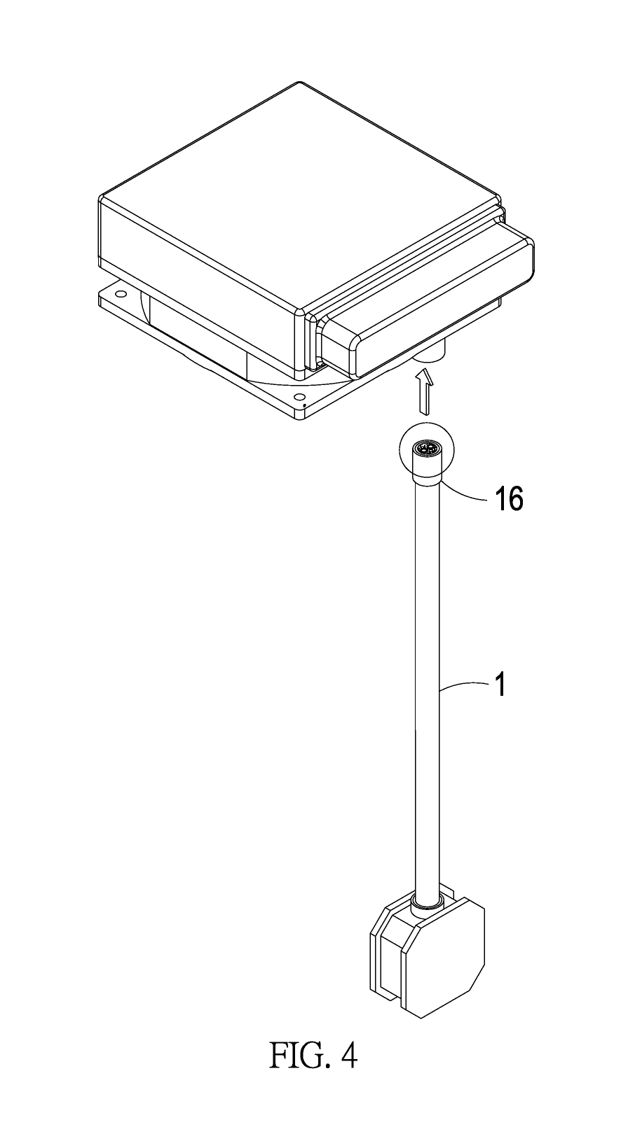

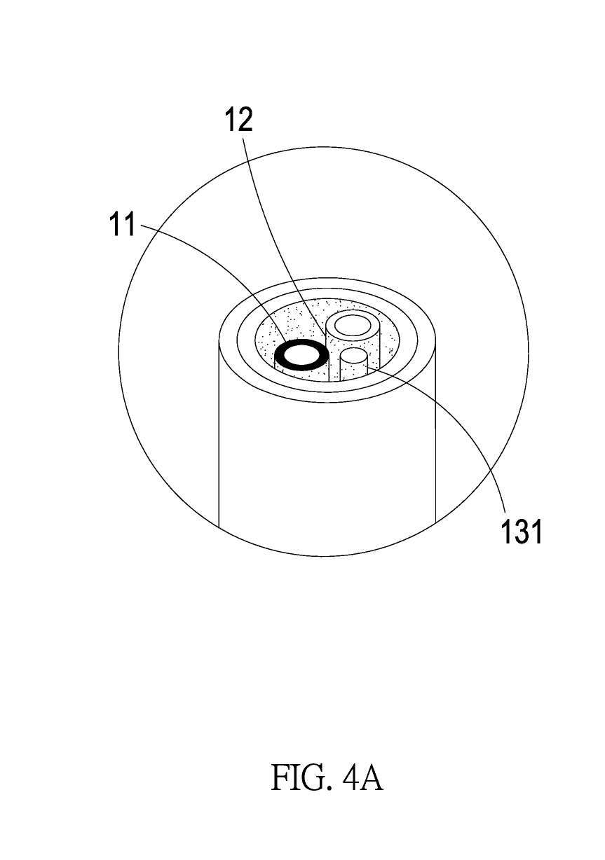

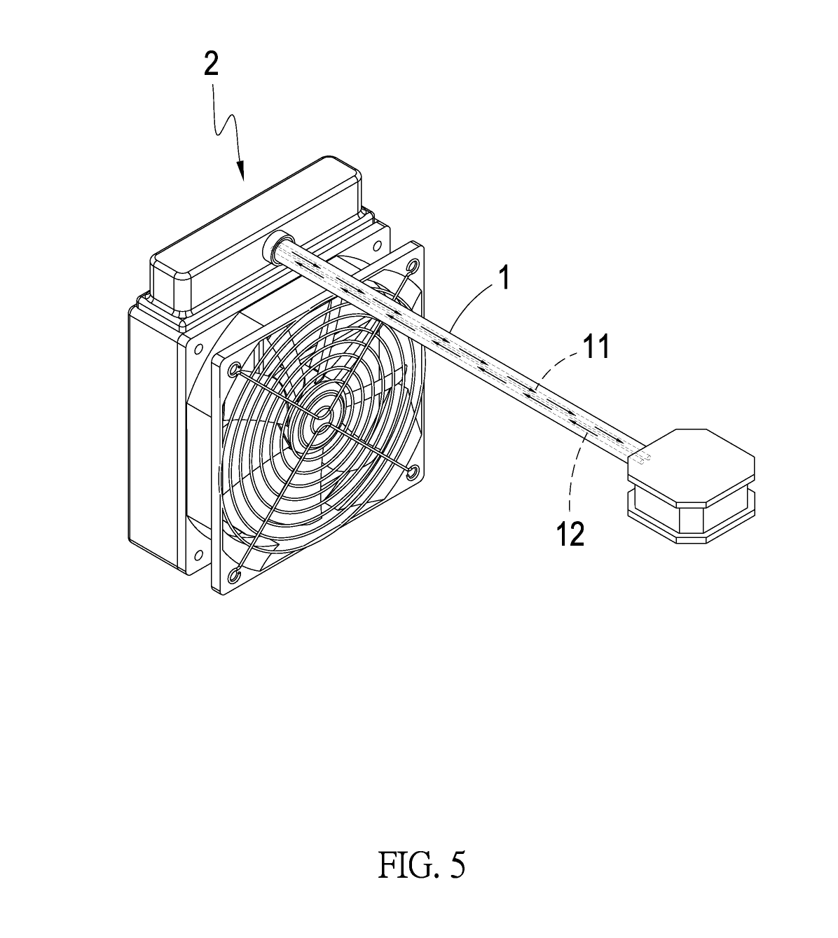

Referring collectively to FIGS. 1-5, which are respectively a perspective view and an exploded view of a preferred embodiment of the present invention, a cross-sectional view taken along line A-A of FIG. 1, and two schematic views illustrating operations of the present invention, these drawings clearly show that with a structure made up of the above-described components, when a user attempts to install the heat dissipation conduit 1 on the water-cooling heat dissipation device 2, since the hot flow tube 11 and the cold flow tube 12 are of an integrated arrangement in combination with the heat dissipation conduit 1, the advantage of the present invention in respect of space is immediately enhanced, this plus the quick connector 16 mounted to an end of the heat dissipation conduit 1 may further shorten the time of installation. Thus, the installation can be completed with a simple operation. In addition, in the installation, the identification section 14 provided at the connection end of the heat dissipation conduit 1 clearly distinguishes the hot flow tube 11 and the cold flow tube 12 from each other so as to reduce human error of an operator in doing assembly and thus indirectly improve operation safety of facility.

Further, the heat dissipation conduit 1 comprises therein the insulator 13 that surrounds each of the hot flow tube 11 and the cold flow tube 12 to allow the insulator 13 to effectively isolate the two tubes, making them independent of each other, so that the cooling performance achieved with the water-cooling heat dissipation device 2 could be improved. In addition, electricity applied to the water-cooling heat dissipation device 2 could be transmitted through the electrically conductive element 131 arranged in the insulator 13 so that no additional electrical conductor is needed, making it practical and useful.

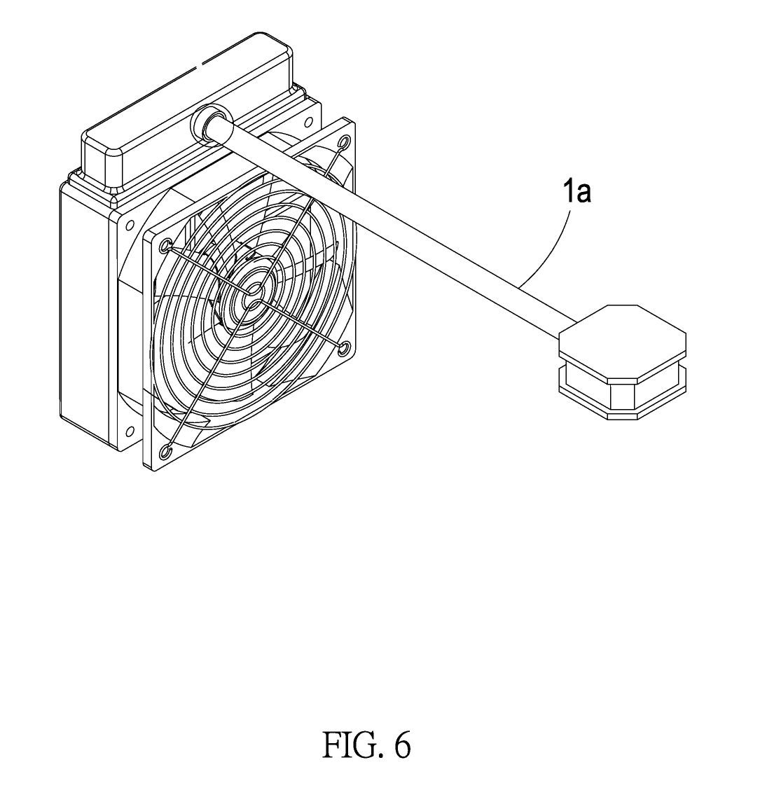

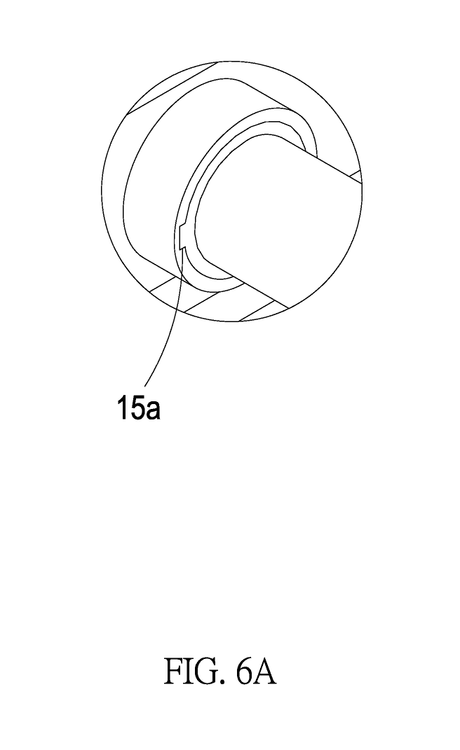

Also referring to FIG. 6, which is a schematic view showing another embodiment of the present invention, the drawing clearly shows that the instant embodiment is similar to the previous embodiment but since the installation of the heat dissipation conduit 1a is generally a direction based operation, a protector element 15a is provided on the connection end of the heat dissipation conduit 1a in order to prevent the hot flow tube and the cold flow tube from being incorrectly connected. As such, with the foolproof measure provided by the protector element 15a on one end of the heat dissipation conduit 1a, an event of incorrectly connecting the hot flow tube and the cold flow tube can be eliminated.

It will be understood that each of the elements described above, or two or more together may also find a useful application in other types of methods differing from the type described above.

While certain novel features of this invention have been shown and described and are pointed out in the annexed claim, it is not intended to be limited to the details above, since it will be understood that various omissions, modifications, substitutions and changes in the forms and details of the device illustrated and in its operation can be made by those skilled in the art without departing in any way from the claims of the present invention.

I claim:

1. A water-cooling piping system, comprising:
at least one heat dissipation conduit, which is connected to at least one water-cooling heat dissipation device;
a hot flow tube, which is arranged in the heat dissipation conduit;
a cold flow tube, which is arranged in the heat dissipation conduit and beside the hot flow tube; and
an insulator, which is arranged in the heat dissipation conduit, the insulator surrounding an outside wall of each of the hot flow tube and the cold flow tube so as to have the hot flow tube and the cold flow tube isolated from and independent of each other.

2. The water-cooling piping system according to claim 1, wherein the insulator comprises at least one electrically conductive element arranged therein.

3. The water-cooling piping system according to claim 1, wherein the heat dissipation conduit has a connection end on which at least one identification section is provided for distinguishing the hot flow tube and the cold flow tube from each other.

4. The water-cooling piping system according to claim 1, wherein the heat dissipation conduit has an end to which a quick connector is mounted.

5. The water-cooling piping system according to claim 1, wherein the heat dissipation conduit has a connection end to which a protector element is mounted for preventing the hot flow tube and the cold flow tube from incorrectly arranged.

6. The water-cooling piping system according to claim 1, wherein the water-cooling heat dissipation device comprises a water-cooling heat dissipation fan.
